(19) United States
(12) Patent Application Publication
(10) Pub. No.: US 2025/0228037 A1
(43) Pub. Date: Jul. 10, 2025

(54) LIGHT RECEIVING ELEMENT

(71) Applicant: SUMITOMO ELECTRIC INDUSTRIES, LTD., Osaka (JP)

(72) Inventor: Takeshi OKADA, Osaka-shi (JP)

(73) Assignee: SUMITOMO ELECTRIC INDUSTRIES, LTD., Osaka (JP)

(21) Appl. No.: 19/013,509

(22) Filed: Jan. 8, 2025

(30) Foreign Application Priority Data
Jan. 10, 2024 (JP) 2024-002067

(51) Int. Cl. H10F 77/30; H10F 30/225; H10F 77/14

(52) U.S. Cl. CPC H10F 77/334; H10F 30/225; H10F 77/147

(57) ABSTRACT

A light receiving element includes a first semiconductor layer having a first conductivity type, a light absorbing layer stacked above the first semiconductor layer, a second semiconductor layer stacked above the light absorbing layer and having a second conductivity type, a first electrode electrically connected to the first semiconductor layer, a second electrode electrically connected to the second semiconductor layer, a first insulating film, and a light shielding film provided on or above the first insulating film. A light receiving region is formed at a portion overlapping the light absorbing layer, the first insulating film is configured to cover a periphery of the light receiving region, and the light shielding film is configured to cover the periphery of the light receiving region and has a light transmittance lower than a light transmittance of the first insulating film.

### CROSS REFERENCE TO RELATED APPLICATIONS

This application claims priority based on Japanese Patent Application No. 2024-002067 filed on Jan. 10, 2024, and the entire contents of the Japanese patent application are incorporated herein by reference.

### TECHNICAL FIELD

The present disclosure relates to a light receiving element.

### BACKGROUND OF THE INVENTION

A light receiving element includes a plurality of semiconductor layers and an electrode. The plurality of semiconductor layers include a light absorbing layer (for example, Japanese Unexamined Patent Application Publication No. H1-161778, Japanese Unexamined Patent Application Publication No. H2-240974, and Japanese Unexamined Patent Application Publication No. H5-013798). A light receiving region for receiving light is provided. By applying a reverse bias voltage to the electrode, a depletion layer spreads in the light absorbing layer of the light receiving region. Carriers (electrons and holes) generated by the absorption of light drift due to the electric field in the depletion layer and are output as photocurrent.

### SUMMARY OF THE INVENTION

A light receiving element according to the present disclosure includes a first semiconductor layer having a first conductivity type, a light absorbing layer stacked above the first semiconductor layer, a second semiconductor layer stacked above the light absorbing layer and having a second conductivity type, a first electrode electrically connected to the first semiconductor layer, a second electrode electrically connected to the second semiconductor layer, a first insulating film, and a light shielding film provided on or above the first insulating film. A light receiving region is formed at a portion overlapping the light absorbing layer, the first insulating film is configured to cover a periphery of the light receiving region, and the light shielding film is configured to cover the periphery of the light receiving region and has a light transmittance lower than a light transmittance of the first insulating film.

### BRIEF DESCRIPTION OF THE DRAWINGS

FIG. 1 is a plan view illustrating a light receiving element according to a first embodiment.

FIG. 2A is a cross-sectional view illustrating a light receiving element.

FIG. 2B is an enlarged view of a mesa and its vicinity.

FIG. 3 is a schematic view illustrating an example of use of a light receiving element.

FIG. 4 is a cross-sectional view illustrating a light receiving element according to a second embodiment.

### DETAILED DESCRIPTION

Even when light is incident from outside the light receiving region, carriers are generated. Noise is generated due to carriers generated outside the light receiving region. Thus, it is an object of the present disclosure to provide a light receiving element capable of reducing noise.

### Description of Embodiments of Present Disclosure

First, the contents of embodiments of the present disclosure will be listed and explained.

(1) A light receiving element according to one aspect of the present disclosure includes a first semiconductor layer having a first conductivity type, a light absorbing layer stacked above the first semiconductor layer, a second semiconductor layer stacked above the light absorbing layer and having a second conductivity type, a first electrode electrically connected to the first semiconductor layer, a second electrode electrically connected to the second semiconductor layer, a first insulating film, and a light shielding film provided on or above the first insulating film. A light receiving region is formed at a portion overlapping the light absorbing layer, the first insulating film is configured to cover a periphery of the light receiving region, and the light shielding film is configured to cover the periphery of the light receiving region and has a light transmittance lower than a light transmittance of the first insulating film. Light incident to the outside of the light receiving region is blocked by the light shielding film and thus is less likely to reach the light absorbing layer. Thus, noise can be reduced.

(2) In the above (1), the light shielding film may be formed of metal and may be electrically unconnected to the first electrode and the second electrode. The metal light shielding film can effectively block light and reduce noise. Since the light shielding film is electrically unconnected to the first electrode and the second electrode, the influence of the light shielding film on the electric field distribution is suppressed.

(3) In the above (1) or (2), the light shielding film may contain gold. The light shielding film can effectively shield light.

(4) In any one of the above (1) to (3), the light receiving element may further include a second insulating film provided on the second electrode and the first insulating film. The light shielding film may be provided on the second insulating film. The light shielding film is insulated from the second electrode by the second insulating film. The influence of the light shielding film on the electric field distribution is suppressed.

(5) In any one of the above (1) to (4), the light receiving element may have a first mesa, the first mesa may include the second semiconductor layer and may be located above the light absorbing layer, the light receiving region may be formed at a top surface of the first mesa, and the light shielding film may be configured to cover a portion of the top surface of the first mesa outside the light receiving region and a side surface of the first mesa. Light incident to the outside of the light receiving region is blocked by the light shielding film. Noise can be reduced.

(6) In the above (5), the light receiving element may further include a window layer. The first mesa may include the second semiconductor layer and the window layer, at a portion of the first mesa overlapping the light receiving region, the second semiconductor layer may be unprovided and the window layer is provided, and the window layer and the second semiconductor layer may be stacked outside the light receiving region of the first mesa. Light incident on the light receiving region is transmitted through the window layer and absorbed by the light absorbing layer. Light incident on the light receiving region can be detected.

(7) In the above (5) or (6), the side surface of the first mesa may be inclined from a direction in which the first semiconductor layer, the light absorbing layer, and the second semiconductor layer are stacked. The light shielding film covers the side surface of the first mesa, and thus can block light.

(8) In any one of the above (5) to (7), the light receiving element may have a second mesa, the second mesa may include the light absorbing layer, the first mesa may be located above the second mesa, a side surface of the second mesa may be located outside the side surface of the first mesa, and the light shielding film may be configured to cover a top surface and the side surface of the second mesa. Light can be blocked.

(9) In any one of the above (1) to (8), the light receiving element may be an avalanche photodiode. Noise can be reduced and the sensitivity of the avalanche photodiode can be increased.

### Details of Embodiments of Present Disclosure

Specific examples of the light receiving element according to the embodiments of the present disclosure will be described below with reference to the drawings. The present disclosure is not limited to these examples, but is defined by the scope of the claims, and is intended to include all modifications within the meaning and scope equivalent to the scope of the claims.

### First Embodiment

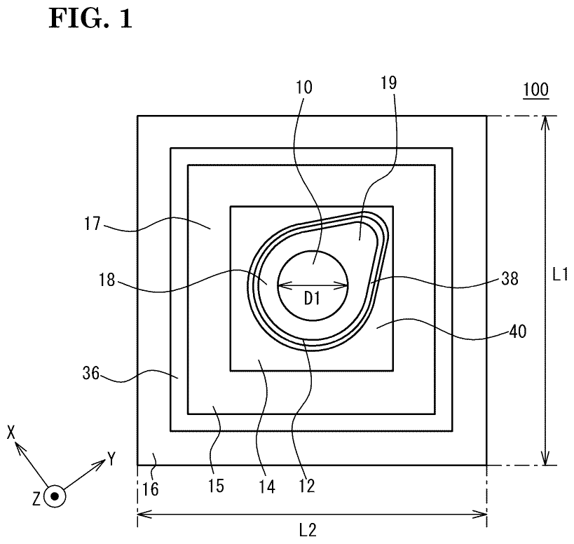

FIG. 1 is a plan view illustrating a light receiving element 100 according to a first embodiment. Light receiving element 100 is, for example, an avalanche photodiode (APD), and receives light and outputs electric signal. The light to be detected is, for example, infrared light having a wavelength of 1.55 μm. A planar shape of light receiving element 100 is rectangular. A top surface of light receiving element 100 is parallel to an XY plane. The lengths L1 and L2 of the sides of light receiving element 100 in the XY plane are, for example, 0.9 mm. The Z-axis direction is a thickness direction of light receiving element 100. A thickness of light receiving element 100 is, for example, 0.625 mm. The X-axis direction, the Y-axis direction, and the Z-axis direction are orthogonal to each other.

Light receiving element 100 includes a light receiving region 10, a mesa 12 (first mesa), a mesa 14 (second mesa), and an outer periphery 16. In the XY plane, mesa 12 is located at the center of mesa 14. Mesa 14 has a portion overlapping mesa 12 and extends outward from mesa 12. A recess 15 is provided between mesa 14 and outer periphery 16. Recess 15 surrounds mesa 14. Outer periphery 16 is located outside recess 15 and surrounds mesa 14. An electrode 17 (first electrode) is provided in recess 15. An electrode 18 (second electrode) is provided on mesa 12. Electrode 18 has a pad 19.

Light receiving region 10 is provided at the center of mesa 12. A planar shape of light receiving region 10 is circular. A diameter D1 of light receiving region 10 is 200 μm, for example. Light receiving element 100 detects light incident on light receiving region 10 and outputs photocurrent.

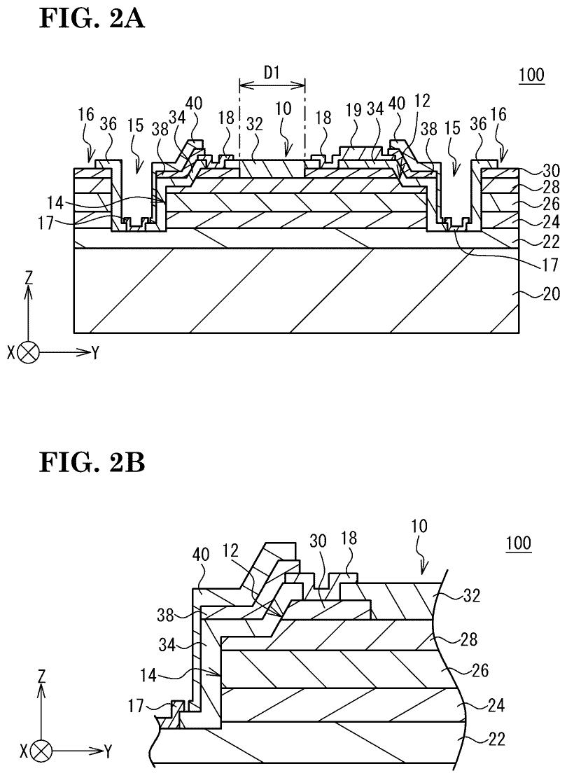

FIG. 2A is a cross-sectional view illustrating light receiving element 100. FIG. 2B is an enlarged view of mesa 12 and its vicinity, illustrating an area from light receiving region 10 to an end of mesa 12.

As shown in FIG. 2A, light receiving element 100 includes a substrate 20, a contact layer 22 (first semiconductor layer), a multiplication layer 24, a light absorbing layer 26, a window layer 28, and a contact layer 30 (second semiconductor layer). These semiconductor layers are stacked in the Z-axis direction.

Substrate 20 is located under mesa 12, mesa 14, recess 15, and outer periphery 16. Contact layer 22, multiplication layer 24, light absorbing layer 26, window layer 28, and contact layer 30 are stacked in this order on substrate 20.

Outer periphery 16 includes contact layer 22, multiplication layer 24, light absorbing layer 26, window layer 28, and contact layer 30. Multiplication layer 24, light absorbing layer 26, window layer 28, and contact layer 30 are unprovided at a portion overlapping recess 15, and contact layer 22 is provided. A portion of contact layer 22 that is to be a bottom surface of recess 15 is recessed from an interface between contact layer 22 and multiplication layer 24.

As shown in FIGS. 2A and 2B, mesa 14 includes contact layer 22, multiplication layer 24, light absorbing layer 26, and window layer 28. Mesa 12 is located above mesa 14 and includes window layer 28 and contact layer 30.

In the XY plane, mesa 14 extends outward from mesa 12. A side surface of mesa 14 includes contact layer 22, multiplication layer 24, light absorbing layer 26, and window layer 28.

A part of window layer 28 is located outside mesa 12 and is recessed from an interface between window layer 28 and contact layer 30. Compared to the part of window layer 28, a portion of window layer 28 included in mesa 12 protrudes in the Z-axis direction. Contact layer 30 is stacked on the protruding portion of window layer 28. A side surface of mesa 12 includes window layer 28 and contact layer 30, and is inclined from the Z-axis direction.

Light receiving region 10 is provided at a top surface of mesa 12. Light receiving region 10 is unprovided with contact layer 30, and is provided with window layer 28. Window layer 28 and contact layer 30 are provided in a portion of mesa 12 outside light receiving region 10.

Light receiving element 100 includes an insulating film 32, an insulating film 34 (first insulating film), an insulating film 36, and an insulating film 38 (second insulating film). Insulating film 36 covers a side surface and a part of a top surface of outer periphery 16. Insulating film 32 is provided on light receiving region 10, covers a top surface of window layer 28, and covers a part of contact layer 30 so as to surround the light receiving region 10. Insulating film 34 is continuously provided from the top surface of mesa 12 to the bottom surface of recess 15. Insulating film 34 covers a top surface of contact layer 30, the side surface of mesa 12, a top surface and a side surface of mesa 14, and a part of the bottom surface of recess 15.

Insulating film 34 is spaced apart from insulating film 32 and insulating film 36. Contact layer 22 is located between insulating film 34 and insulating film 36 inside recess 15. Electrode 17 is provided between insulating film 34 and insulating film 36, and is electrically connected to contact layer 22. Portions of electrode 17 are placed on a top surface of insulating film 34 and a top surface of insulating film 36.

Contact layer 30 is located on mesa 12 between insulating film 32 and insulating film 34. Electrode 18 is provided on mesa 12 and electrically connected to contact layer 30 between insulating film 32 and insulating film 34. Portions of electrode 18 are placed on a top surface of insulating film 32 and the top surface of insulating film 34. As shown in FIG. 1, electrode 18 surrounds light receiving region 10.

Insulating film 38 is provided above the top surface of mesa 12, the side surface of mesa 12, and the top surface of mesa 14. Insulating film 38 is unprovided in light receiving region 10, is located outside light receiving region 10 and covers a periphery of light receiving region 10 so as to surround the light receiving region 10. Insulating film 38 covers a part of insulating film 34 and a part of electrode 18.

A light shielding film 40 is continuously provided from the top surface of mesa 12 to the bottom surface of recess 15. Light shielding film 40 covers a portion of the top surface of mesa 12 outside light receiving region 10, and covers the side surface of mesa 12 and the top surface and the side surface of mesa 14. Light shielding film 40 is provided on a surface of insulating film 38 above mesa 12 and mesa 14, and is provided on a surface of insulating film 34 on the side surface of mesa 14 so as to surround the light receiving region 10. Light shielding film 40 is spaced apart from electrode 17 and is electrically unconnected to electrode 17. Insulating film 38 is provided between light shielding film 40 and electrode 18, and light shielding film 40 is electrically unconnected to electrode 18.

Substrate 20 is formed of, for example, indium phosphide (InP). Contact layer 22 has an n-type conductivity type (first conductivity type), and is formed of, for example, n-type indium gallium arsenide (n-InGaAs) having a thickness of 1.5 μm. Multiplication layer 24 is formed of, for example, non-doped aluminum indium arsenide (AlInAs) having a thickness of 0.6 μm. Light absorbing layer 26 is formed of, for example, InGaAs having a thickness of 1 μm. Window layer 28 is formed of, for example, AlInAs having a thickness of 2.7 μm. Contact layer 30 has a p-type conductivity type (second conductivity type) and is formed of, for example, p-InGaAs having a thickness of 0.2 μm. Light receiving element 100 may include a semiconductor layer other than the above. The semiconductor layer may be formed of a compound semiconductor layer other than the above.

Electrode 17 and electrode 18 are formed of metal. Insulating film 32, insulating film 34, insulating film 36, and insulating film 38 are formed of an insulator such as silicon nitride (SiN). The thickness of each insulating film is, for example, 200 nm. Insulating film 32 is an antireflection coating (AR coating). Insulating film 34, insulating film 36, and insulating film 38 may be high reflection coatings (HR coating) or AR coatings.

Light shielding film 40 is, for example, a metallic layer, and includes a titanium (Ti) layer having a thickness of 50 nm and a gold (Au) layer having a thickness of 450 nm. The Ti layer is stacked on insulating film 38, and the Au layer is stacked on the Ti layer. The transmittance of light shielding film 40 with respect to the light to be detected is lower than that of the insulating films such as insulating film 34.

### Manufacturing Method

For example, contact layer 22, multiplication layer 24, light absorbing layer 26, window layer 28, and contact layer 30 are epitaxially grown in this order on a top surface of substrate 20 by metal organic chemical vapor deposition (MOCVD) method.

The layers from contact layer 30 to multiplication layer 24 are etched, and a part of contact layer 22 is etched, thereby forming recess 15. Outer periphery 16 is formed outside recess 15. Mesa 14 is formed at a portion surrounded by recess 15. By etching, a slope located in inward the side surface of mesa 14 is formed from contact layer 30 to window layer 28, and mesa 12 is formed. By etching, contact layer 30 is removed from a part of the top surface of mesa 12. Window layer 28 is exposed from contact layer 30 in light receiving region 10.

For example, insulating film 32, insulating film 34, and insulating film 36 are deposited by a plasma enhanced CVD (PECVD) method. Electrode 17 and electrode 18 are formed by vacuum deposition and lift-off. Insulating film 38 is deposited by the plasma enhanced CVD method. Light shielding film 40 is formed by vacuum deposition and lift-off. Light receiving element 100 is formed by the above process.

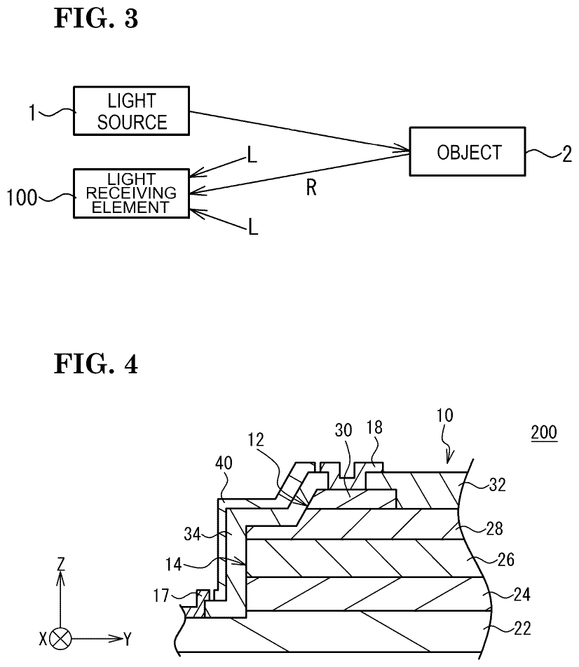

FIG. 3 is a schematic view illustrating an example of use of light receiving element 100. A light source 1 is, for example, a laser element, and irradiates an object 2 with light. The light is reflected from object 2, and reflected light R is generated. The orientation of light receiving element 100 is adjusted so that the reflected light R is incident on light receiving region 10 of light receiving element 100. Light receiving element 100 detects the reflected light R from object 2. The wavelength of the light to be detected is, for example, 1.55 μm.

When light receiving element 100 is used, a reverse bias voltage is applied. A positive voltage is applied to electrode 17, and a negative voltage is applied to electrode 18. By applying the reverse bias voltage, a depletion layer spreads to light absorbing layer 26 under light receiving region 10. Light is incident on light receiving region 10. Insulating film 32 is AR coating, and has a high transmittance with respect to light having a wavelength of 1.55 μm. The transmittance is, for example, 90% or more, 95% or more, or 99% or more. The band gap of window layer 28 is larger than the energy of the light to be detected. The light passes through insulating film 32 and window layer 28 and is incident on light absorbing layer 26. Light absorbing layer 26 absorbs light and generates carriers. The carriers drift by the electric field applied to the depletion layer, and are output as photocurrent.

As shown in FIG. 3, light L other than the reflected light R may be incident on light receiving element 100. The light L is reflected light generated from an object other than object 2, and light from a light source other than light source 1, such as the sun and illumination. Sunlight includes a plurality of wavelengths such as 1.55 μm. The light L may propagate from a direction different from that of the reflected light R and may incident to the outside of light receiving region 10.

Carriers are generated by absorption of light incident from the outside of light receiving region 10. Such carriers may cause noise. These carriers diffuse more slowly than carriers generated near the depletion layer. Thus, the response speed may be reduced.

According to the first embodiment, insulating film 34 covers the periphery of light receiving region 10. Light shielding film 40 is provided on or above insulating film 34 and covers the periphery of light receiving region 10. A transmittance of light shielding film 40 with respect to the light is lower than a transmittance of insulating film 34. Light incident to the outside of light receiving region 10 is blocked by light shielding film 40 and thus is less likely to reach light absorbing layer 26. Light absorbing layer 26 is less likely to absorb the light incident from the outside of light receiving region 10, and carrier generation at a position far from the depletion layer is suppressed. As a result, noise can be reduced.

Light absorbing layer 26 absorbs light incident on light receiving region 10 and generates carriers. The reduction in noise improves the sensitivity of light receiving element 100 and reduces a decrease in response speed.

As shown in FIG. 3, light may be incident on light receiving element 100 from a plurality of directions. Light incident to the outside of light receiving region 10 is cut by light shielding film 40. Light receiving element 100 detects light incident on light receiving region 10. Light receiving element 100 is, for example, an avalanche photodiode, and is required to have high sensitivity. According to the embodiment, noise can be reduced and the sensitivity of the avalanche photodiode can be increased.

It is only necessary that the transmittance of light shielding film 40 is lower than the transmittance of insulating film 34. The transmittance of light shielding film 40 with respect to the light to be detected is, for example, 10% or less, 5% or less, or 1% or less. The material of light shielding film 40 may be a metal or an insulator. Generally, light shielding film 40 of metal has a lower transmittance than an insulator. Light can be effectively shielded. Light shielding film 40 can more effectively shield light by containing, for example, gold. Since light shielding film 40 is made of metal, light shielding film 40 can be deposited by the same apparatus as that for the electrode. The process is simplified.

Light shielding film 40 is electrically unconnected to electrode 17 and electrode 18. The influence of light shielding film 40 on the electric field distribution is suppressed. The characteristics of light receiving element 100 are less likely to change. Edge breakdown due to electric field concentration is less likely to occur.

Insulating film 38 is provided on electrode 18 and insulating film 34. Light shielding film 40 is provided on insulating film 38. Insulating film 38 is provided between light shielding film 40 and electrode 18, and thus light shielding film 40 is insulated from electrode 18. Light shielding film 40 is spaced apart from and insulated from electrode 17. The change in the electric field distribution is suppressed.

Light receiving element 100 has mesa 12. Light receiving region 10 is formed at the top surface of mesa 12. Light shielding film 40 covers a portion of the top surface of mesa 12 outside light receiving region 10 and the side surface of mesa 12. Light incident to the outside of light receiving region 10 is blocked by light shielding film 40. Noise can be reduced. Light shielding film 40 surrounds the entire light receiving region 10 in the XY plane, thereby effectively shielding light.

Contact layer 30 is stacked on window layer 28 outside light receiving region 10 of mesa 12. Electrode 18 is connected to contact layer 30. Light receiving region 10 is unprovided with contact layer 30, and is provided with window layer 28. The band gap of window layer 28 is larger than the energy of infrared light, for example. The infrared light is transmitted through window layer 28 of light receiving region 10 and absorbed by light absorbing layer 26. Light incident on light receiving region 10 can be detected. The wavelength of the light to be detected may be 1.55 μm or may be other than 1.55 μm.

Insulating film 34 may be HR coating. However, the reflectance of insulating film 34 varies depending on the incident angle of light. The reflectance of insulating film 34 is highest for light that is incident perpendicularly, and is low for light that is incident at an angle different from the perpendicular. For example, light receiving element 100 detect light by the light being perpendicularly incident on light receiving region 10. The side surface of mesa 12 is inclined from the Z-axis direction. Thus, the incident angle of light to the side surface is different from the incident angle to light receiving region 10. Even when insulating film 34 is HR coating, light may be transmitted. Light shielding film 40 is provided on or above insulating film 34 and covers the side surface of mesa 12. Light shielding film 40 can shield light. Noise can be reduced.

Insulating film 32 is AR coating to transmit light from light receiving region 10. Insulating film 34 and insulating film 36 may be HR coating or AR coating. Insulating film 38 may be formed of the same material as insulating film 32 or the like. Since a plurality of insulating films can be deposited with the same apparatus, the process is simplified.

Light receiving element 100 has mesa 14. Mesa 14 includes contact layer 22, multiplication layer 24, and light absorbing layer 26. The side surface of mesa 14 is located outside the side surface of mesa 12. Light shielding film 40 covers the top surface and the side surface of mesa 14 with respect to the light receiving region 10 in a plan view of the light receiving element 100. Light that has propagated to mesa 14 is blocked by light shielding film 40. Noise can be reduced.

Light absorbing layer 26 is not included in mesa 12, and is included in mesa 14. The electric field is distributed at a portion overlapping mesa 14 in the Z-axis direction, and the electric field is less likely to be applied to an edge of light absorbing layer 26. Dark current can be reduced. Two or more stages of mesa may be provided on mesa 14. Light receiving region 10 is formed in the uppermost mesa. The electric field is distributed inside the mesa and is less likely to leak out of the mesa. The characteristics of the light receiving element are improved.

### Second Embodiment

FIG. 4 is a cross-sectional view illustrating a light receiving element 200 according to a second embodiment, which is an enlarged view similar to FIG. 2B. The description of the same configuration as that of the first embodiment will be omitted.

As shown in FIG. 4, light receiving element 200 does not have insulating film 38. Light shielding film 40 is provided on the surface of insulating film 34. Light shielding film 40 is spaced apart from electrode 17 and electrode 18, and is electrically unconnected to the electrodes.

According to the second embodiment, light shielding film 40 covers the periphery of light receiving region 10. Light incident to the outside of light receiving region 10 is blocked by light shielding film 40. Noise can be reduced.

Since insulating film 38 is not necessarily provided, the process is simplified. Insulating film 34 is located between electrode 18 and light shielding film 40, and is HR coating. Insulating film 34 of HR coating is less likely to transmit light than AR coating. The distance between light shielding film 40 and electrode 18 is, for example, 10 μm or less, or 5 μm or less. The narrower the gap, the less light is transmitted.

Although the embodiments of the present disclosure have been described in detail, the present disclosure is not limited to the specific embodiments, and various modifications and changes can be made within the scope of the gist of the present disclosure described in the claims.

1. A light receiving element comprising:
a first semiconductor layer having a first conductivity type;
a light absorbing layer stacked above the first semiconductor layer;
a second semiconductor layer stacked above the light absorbing layer and having a second conductivity type;
a first electrode electrically connected to the first semiconductor layer;
a second electrode electrically connected to the second semiconductor layer;
a first insulating film; and
a light shielding film provided on or above the first insulating film,
wherein a light receiving region is formed at a portion overlapping the light absorbing layer,
the first insulating film is configured to cover a periphery of the light receiving region, and
the light shielding film is configured to cover the periphery of the light receiving region and has a light transmittance lower than a light transmittance of the first insulating film.

2. The light receiving element according to claim 1, wherein the light shielding film is formed of metal and is electrically unconnected to the first electrode and the second electrode.

3. The light receiving element according to claim 2, wherein the light shielding film contains gold.

4. The light receiving element according to claim 1, further comprising:
a second insulating film provided on the second electrode and the first insulating film,
wherein the light shielding film is provided on the second insulating film.

5. The light receiving element according to claim 1,
wherein the light receiving element has a first mesa,
the first mesa includes the second semiconductor layer and is located above the light absorbing layer,
the light receiving region is formed at a top surface of the first mesa, and
the light shielding film is configured to cover a portion of the top surface of the first mesa outside the light receiving region and a side surface of the first mesa.

6. The light receiving element according to claim 5, further comprising:
a window layer,
wherein the first mesa includes the second semiconductor layer and the window layer,
at a portion of the first mesa overlapping the light receiving region, the second semiconductor layer is unprovided and the window layer is provided, and
the window layer and the second semiconductor layer are stacked outside the light receiving region of the first mesa.

7. The light receiving element according to claim 5, wherein the side surface of the first mesa is inclined from a direction in which the first semiconductor layer, the light absorbing layer, and the second semiconductor layer are stacked.

8. The light receiving element according to claim 5,
wherein the light receiving element has a second mesa,
the second mesa includes the light absorbing layer,
the first mesa is located above the second mesa,
a side surface of the second mesa is located outside the side surface of the first mesa, and
the light shielding film is configured to cover a top surface and the side surface of the second mesa.

9. The light receiving element according to claim 1, wherein the light receiving element is an avalanche photodiode.
